(19) United States
(12) Patent Application Publication
(10) Pub. No.: US 2018/0348565 A1
(43) Pub. Date: Dec. 6, 2018

(54) DISPLAY PANEL AND MANUFACTURING METHOD THEREOF

(71) Applicants: HKC Corporation Limited, Shenzhen (CN); Chongqing HKC Optoelectronics Technology Co., ltd., Chongqing (CN)

(72) Inventor: CHUNG-KUANG CHIEN, Chongqing (CN)

(21) Appl. No.: 15/848,940

(22) Filed: Dec. 20, 2017

Related U.S. Application Data
(63) Continuation of application No. PCT/CN2017/091406, filed on Jul. 3, 2017.

(30) Foreign Application Priority Data
Jun. 6, 2017 (CN) 201710419498.9

(51) Int. Cl. G02F 1/1339; H01L 27/12; H01L 29/49; G02F 1/136

(52) U.S. Cl. CPC G02F 1/13394; H01L 27/1259; H01L 29/42384; G02F 1/136; H01L 29/4908

(57) ABSTRACT

The present application discloses a display panel and the manufacturing method thereof, the display panel includes a first substrate; a second substrate; photo spacers disposed between the first substrate and the second substrate, the first substrate used for carrying the photo spacers; the second substrate used for pressing the photo spacers; the photo spacers comprising a pressing material layer, the pressing material layer being cured and shaped when subjected to a pressure.

### FIELD OF THE DISCLOSURE

The disclosure relates to a display technology field, and more particularly to a display panel and a manufacturing method thereof.

### BACKGROUND

The liquid crystal display with a compact body, power saving, no radiation and many other advantages, has been widely application. Most of the liquid crystal display in the market is a backlight type liquid crystal display; the backlight type liquid crystal display includes a liquid crystals panel and a backlight module. The working principle of the liquid crystal display is placing liquid crystals in two parallel glass substrate, and applying driving voltage to control the direction of rotation of the molecule the liquid crystals between the two glass substrates to reflect the light from the backlight module to produce an image.

Wherein Thin Film Transistor-liquid Crystal Display (TFT-LCD) has gradually dominated the display field due to its low power consumption, excellent picture quality and high production yield. The similarly, the thin film transistor liquid crystal display includes a liquid crystals panel and a backlight module, and the liquid crystals panel includes a color filter substrate (CF Substrate, also known as a color filter substrate) and a thin film transistor substrate (TFT Substrate) and a mask, a transparent electrode is present on the inner side of the substrate. A layer of liquid crystals (LC) is present between the two substrates.

However, photo spacers (PS) are disposed between the two substrates and used to keep the two substrates maintain a certain interval, which facilitates the formation of the cell. There a large number of influence factors for the height of the photo spacers, so the uniformity of the height of the photo spacers are not easy to control, the kind of the height of the photo spacers will seriously affect the one drop filling window (ODF window).

### SUMMARY

The technical problem to be solved by the present application is to provide a display panel including photo spacers that is conveniently and stable formed.

In addition, the present application also provides a method for manufacturing the display panel.

In addition, the present application also provides a display apparatus.

The present application can be achieved by the following technical approach.

A display panel includes: a first substrate, a second substrate, photo spacers disposed between the first substrate and the second substrate. Wherein the first substrate is used for carrying the photo spacers; the second substrate is used for pressing the photo spacers. Wherein the photo spacers include a pressing material layer, the pressing material layer is cured and shaped when subjected to a pressure.

Wherein the photo spacers disposed on the first substrate, the second substrate bonded to the photo spacers and applying pressure to the photo spacers. Compared to the siphon injection mode of liquid crystals under vacuum, by using the method of one drop filling (ODF) to inject the liquid crystals are time saving, saving the liquid crystals material and low contamination rate of the liquid crystals material and the cost is reduced as it can also be the material for applying pressure to photo spacers and saving cost.

Wherein the first substrate includes active switches, the photo spacers are disposed on the active switches, the photo spacers includes first end faces and second end faces, the first end faces are in contact with and connected to the first substrate, the second end faces are in contact with and connected to the second substrate, contact areas of the first end faces and the first substrate are larger than contact areas of the second end faces and the second substrate; a substrate with the active switches used for the substrate carrying the photo spacers are as a specific embodiment.

Wherein the first substrate includes a color filter layer, the photo spacers are disposed on the color filter layer, the photo spacers includes first end faces and second end faces, the first end faces are in contact with and connected to the first substrate, the second end faces are in contact with and connected to the second substrate, and contact areas of the first end faces and the first substrate are larger than contact areas of the second end faces and the second substrate; a substrate with the color filter layer used for the substrate carrying the photo spacers are as a specific embodiment.

Wherein the first substrate includes active switches and an color filter layer, the photo spacers are disposed on the active switches and the color filter layer, the photo spacers includes first end faces and second end faces, the first end faces are in contact with and connected to the first substrate, the second end faces are in contact with and connected to the second substrate, and contact areas of the first end faces and the first substrate are larger than contact areas of the second end faces and the second substrate.

Wherein the color filter layer includes color resist regions; the active switches includes a protective layer and a transparent conductive layer, the protective layer and the transparent conductive layer are disposed on the corresponding color resist regions; the side portion of the color resist region includes a capping layer; the capping layer is formed by the protective layer and the transparent conductive layer between two adjacent color resist regions of the two sides of the corresponding color resist regions; and the active switches are disposed on the first substrate. When the second substrate is bonded to the photo spacers and applying pressure to the photo spacers, the capping layer is formed. The formed capping layer can be used as a feature of the display panel, easy for inspection, and improved the yield.

According to another aspect of the present application, the present application also discloses a method for manufacturing a display panel, the display panel including a first substrate used for carrying photo spacers and a second substrate used for pressing the photo spacers; the method including the steps of:

Disposing photo spacers between the first substrate and the second substrate;

Bonding the second substrate to the photo spacers and applying pressure to the photo spacers; and

The photo spacers include a pressing material layer, the pressing material layer is cured and shaped when subjected to a pressure.

Wherein the display panel further including a frame and liquid crystals, the steps between disposing photo spacers between the first substrate and the second substrate and bonding the second substrate to the photo spacers and applying pressure to the photo spacers further including the step of:

Setting the frame surrounding the first substrate; and

Drip-feeding the liquid crystals on the first substrate.

The specific step of the One Drop Filling is bonding another substrate after coating of the frame and filling the crystal liquid.

Wherein before the step of disposing photo spacers between the first substrate and the second substrate further including:

Disposing alignment films on opposite inner surfaces of the first substrate and the second substrate,

Coating resists of the photo spacers on the first substrate, and exposing and developing the resist of the photo spacers.

The alignment film (polyimide, PI) can be processed to have the alignment ability and facilitate the arrangement of liquid crystals.

According to another aspect of the present application, the present application also discloses a display apparatus including a backlight module and a display panel as described above.

In the present application, since the photo spacers includes the pressing material layer, the pressing material layer has a function of being cured and shaped when subjected to the pressure, the photo spacers are easily compressed, cured and shaped to reduce variations during the method for manufacturing the photo spacers.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a schematic cross-sectional view of a partial structure of a display panel according to an embodiment of the present application;

FIG. 2 is a schematic flow diagram of the manufacturing method of a display panel of an embodiment of the present application;

FIG. 3 is a schematic structural view of the display panel according to an embodiment of the present application; and

FIG. 4 is a schematic flow diagram of the manufacturing method of the display panel of an embodiment of the present application.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

In the description of the disclosure, terms such as “center”, “transverse”, “above”, “below”, “left”, “right”, “vertical”, “horizontal”, “top”, “bottom”, “inside”, “outside”, etc. for indicating orientations or positional relationships refer to orientations or positional relationships as shown in the drawings; the terms are for the purpose of illustrating the disclosure and simplifying the description rather than indicating or implying the device or element must have a certain orientation and be structured or operated by the certain orientation, and therefore cannot be regarded as limitation with respect to the disclosure. Moreover, terms such as “first” and “second” are merely for the purpose of illustration and cannot be understood as indicating or implying the relative importance or implicitly indicating the number of the technical feature. Therefore, features defined by “first” and “second” can explicitly or implicitly include one or more the features. In the description of the disclosure, unless otherwise indicated, the meaning of “plural” is two or more than two. In addition, the term “comprise” and any variations thereof are meant to cover a non-exclusive inclusion.

In the description of the disclosure, is should be noted that, unless otherwise clearly stated and limited, terms “mounted”, “connected with” and “connected to” should be understood broadly, for instance, can be a fixed connection, a detachable connection or an integral connection; can be a mechanical connection, can also be an electrical connection; can be a direct connection, can also be an indirect connection by an intermediary, can be an internal communication of two elements. A person skilled in the art can understand concrete meanings of the terms in the disclosure as per specific circumstances.

The terms used herein are only for illustrating concrete embodiments rather than limiting the exemplary embodiments. Unless otherwise indicated in the content, singular forms “a” and “an” also include plural. Moreover, the terms “comprise” and/or “include” define the existence of described features, integers, steps, operations, units and/or components, but do not exclude the existence or addition of one or more other features, integers, steps, operations, units, components and/or combinations thereof.

The disclosure will be further described in detail with reference to accompanying drawings and preferred embodiments as follows.

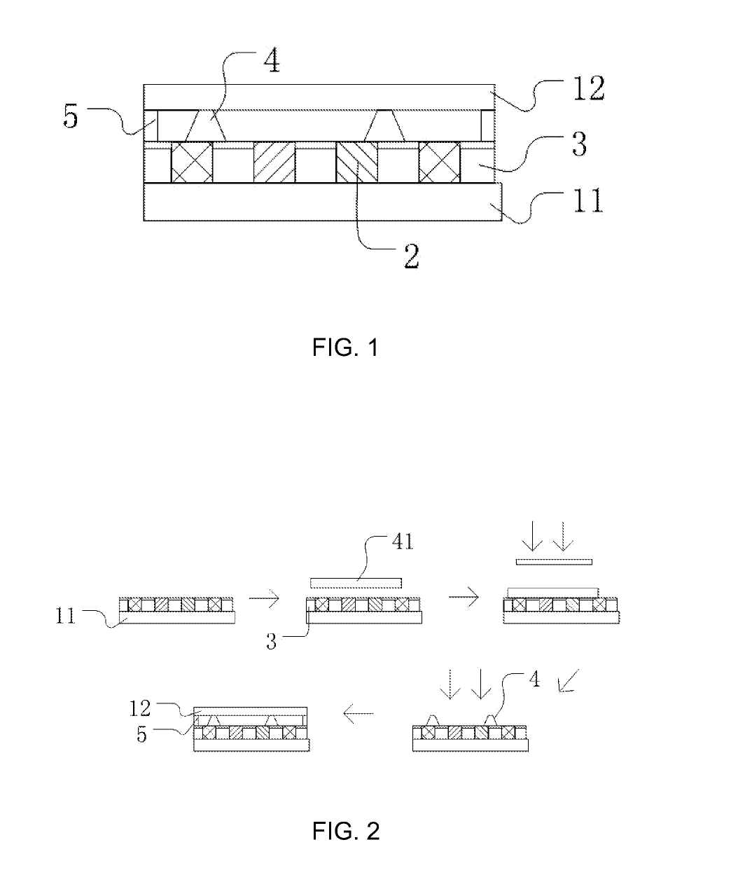

An embodiment of the present application, as illustrated in FIG. 1, the display panel includes a substrate, the substrate including a first substrate 11 for carrying photo spacers 4 and a second substrate 12 for pressing the photo spacers 4; the photo spacers 4 are disposed between the first substrate 11 and the second substrate 12, the photo spacers 4 include a pressing material layer, the pressing material layer has a function of being cured and shaped when subjected to a pressure, the pressing material layer is cured and shaped when subjected to the pressure. The photo spacers 4 include a layer of pressing material layer, the pressing material layer has a function of being cured and shaped when subjected to the pressure, the photo spacers 4 are easily compressed, cured and shaped to reduce variations during the process for manufacturing the photo spacers. The photo spacers 4 are disposed between the two substrates and are used to keep the two substrates maintain a certain interval, which facilitates the formation of the cell.

According to another embodiment of the present application, the display panel includes a substrate, the substrate including a first substrate 11 for carrying photo spacers 4 and a second substrate 12 for pressing the photo spacers 4; the photo spacers 4 are disposed between the first substrate 11 and the second substrate 12, the photo spacers 4 include a pressing material layer, the pressing material layer has a function of being cured and shaped when subjected to a pressure, the pressing material layer is cured and shaped when subjected to the pressure. The photo spacers 4 include a layer of pressing material layer, the pressing material layer has a function of being cured and shaped when subjected to the pressure, the photo spacers4 are easily compressed, cured and shaped to reduce variations during the process for manufacturing the photo spacers. The photo spacers 4 are disposed between the two substrates and are used to keep the two substrates maintain a certain interval, which facilitates the formation of the cell. The photo spacers are disposed on the first substrate, the second substrate is bonded to the photo spacers and applying pressure to the photo spacers. Compared to the siphon injection mode of liquid crystals under vacuum, by using the method of one drop filling to inject the liquid crystals, is time saving, saving the liquid crystals material and low contamination rate of the liquid crystals material and the cost is reduced as it can also be the material for applying pressure to photo spacers and saving cost.

According to another embodiment of the present application, the display panel includes a substrate, the substrate including a first substrate 11 for carrying photo spacers 4 and a second substrate 12 for pressing the photo spacers 4; the photo spacers 4 are disposed between the first substrate 11 and the second substrate 12, the photo spacers 4 include a pressing material layer, the pressing material layer has a function of being cured and shaped when subjected to a pressure, the pressing material layer is cured and shaped when subjected to the pressure. The photo spacers 4 include a layer of pressing material layer, the pressing material layer has a function of being cured and shaped when subjected to the pressure, the photo spacers 4 are easily compressed, cured and shaped to reduce variations during the process for manufacturing the photo spacers. The photo spacers 4 are disposed between the two substrates and are used to keep the two substrates maintain a certain interval, which facilitates the formation of the cell. The photo spacers are disposed on the first substrate, and the second substrate is bonded to the photo spacers and applying pressure to the photo spacers. The first substrate is provide with active switches, the photo spacers are disposed on the active switches, the photo spacers including first end faces and second end faces, the first end faces are in contact with and connected to the first substrate, the second end faces are in contact with and connected to the second substrate, and the contact areas of the first end face and the first substrate is larger than the contact areas of the second end faces and the second substrate.

Compared to the siphon injection mode of liquid crystals, under vacuum, by using the method of one drop filling to inject the liquid crystals, is time saving, saving the liquid crystals material and low contamination rate of the liquid crystals material and the cost is reduced as it can also be the material for applying pressure to photo spacers and saving cost.

According to another embodiment of the present application, the display panel includes a substrate, the substrate including a first substrate 11 for carrying photo spacers 4 and a second substrate 12 for pressing the photo spacers 4; the photo spacers 4 are disposed between the first substrate 11 and the second substrate 12, the photo spacers 4 include a pressing material layer, the pressing material layer has a function of being cured and shaped when subjected to a pressure, the pressing material layer is cured and shaped when subjected to the pressure. The photo spacers 4 include a layer of pressing material layer, the pressing material layer has a function of being cured and shaped when subjected to the pressure, the photo spacers 4 are easily compressed, cured and shaped to reduce variations during the process for manufacturing the photo spacers. The photo spacers 4 are disposed between the two substrates and are used to keep the two substrates maintain a certain interval, which facilitates the formation of the cell. The photo spacers are disposed on the first substrate, and the second substrate is bonded to the photo spacers and applying pressure to the photo spacers. The first substrate is provided with a color filter layer, the photo spacers are disposed on the color filter layer, the photo spacers including first end faces and second end faces, the first end faces are in contact with and connected to the first substrate, the second end faces are in contact with and connected to the second substrate, and the contact areas of the first end face and the first substrate is larger than the contact areas of the second end faces and the second substrate. Compared to the siphon injection mode of liquid crystals, under vacuum, by using the method of one drop filling to inject the liquid crystals, is time saving, saving the liquid crystals material and low contamination rate of the liquid crystals material and the cost is reduced as it can also be the material for applying pressure to photo spacers and saving cost.

Wherein the first substrate 11 is provide with the color filter layer 2 and a black matrix 3, the color filter layer 2 includes, for example, RGB (red, green, blue), but not limited to R pixels, G pixels, B pixels, the color filter layer can have pixels corresponding to the colors include W (white), Y (Yellow) and etc. the color is richer, the performance of the display is also better; the black matrix, BM 3 is used to prevent leakage of the background light, improve display contrast, to prevent color mixing and increase the purity of color.

According to another embodiment of the present application, the display panel includes a substrate, the substrate including a first substrate 11 for carrying photo spacers 4 and a second substrate 12 for pressing the photo spacers 4; the photo spacers 4 are disposed between the first substrate 11 and the second substrate 12, the photo spacers 4 include a pressing material layer, the pressing material layer has a function of being cured and shaped when subjected to a pressure, the pressing material layer is cured and shaped when subjected to the pressure. The photo spacers 4 include a layer of pressing material layer, the pressing material layer has a function of being cured and shaped when subjected to the pressure, the photo spacers 4 are easily compressed, cured and shaped to reduce variations during the method for manufacturing the photo spacers. The photo spacers 4 are disposed between the two substrates and are used to keep the two substrates maintain a certain interval, which facilitates the formation of the cell. The photo spacers are disposed on the first substrate, and the second substrate is bonded to the photo spacers and applying pressure to the photo spacers. The first substrate is provide with the active switches and the color filter layer, the photo spacers are disposed on the active switches and the color filter layer, the photo spacers including first end faces and second end faces, the first end faces are in contact with and connected to the first substrate, the second end faces are in contact with and connected to the second substrate, and the contact areas of the first end face and the first substrate is larger than the contact areas of the second end faces and the second substrate. Compared to the siphon injection mode of liquid crystals, under vacuum, by using the method of one drop filling to inject the liquid crystals, is time saving, saving the liquid crystals material and low contamination rate of the liquid crystals material and the cost is reduced as it can also be the material for applying pressure to photo spacers and saving cost. The end product of the display panel is characterized by a layer of capping layer is around the boundary of all of the RGB color resist.

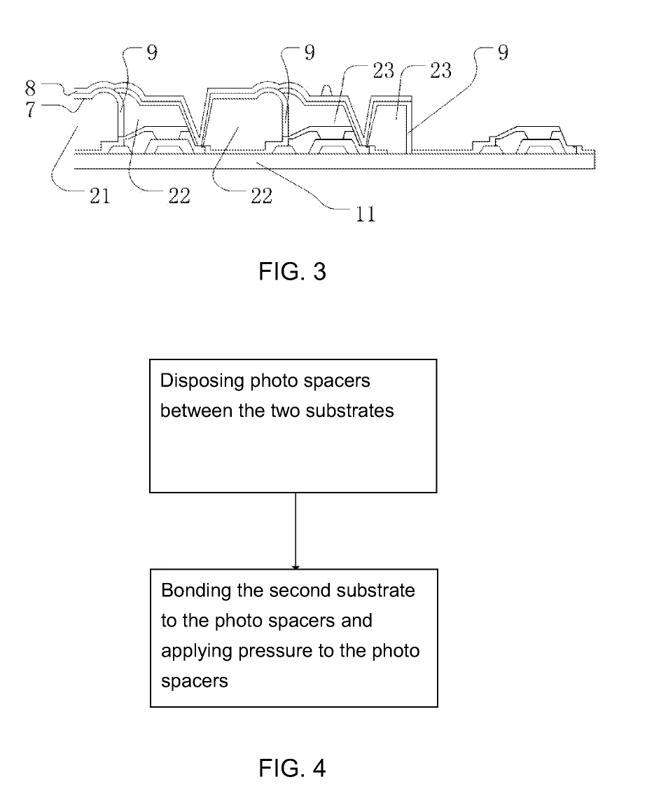

Specifically, as shown in FIG. 3, the active switches are disposed on the first substrate, the color filter layer includes color resist regions (first color resist region 21, second color resist region 22, and third color resist region), the active switches includes a protective layer 7 and a transparent conductive layer 8 disposed on the corresponding color resist region, when the second substrate is bonded to the photo spacers and applying pressure to the photo spacers, the protective layer and the transparent conductive layer between two adjacent color resist regions form a capping layer 9 on both sides of the corresponding color resist regions. The formed capping layer can be used as a feature of the display panel, easy for inspection, and improved the yield. Wherein the first substrate 11 is provided with a color filter layer 2 and a black matrix 3, the color filter layer 2 includes, for example, RGB (red, green, blue), but not limited to R pixels (first color resist region), G pixels (second color resist region), B pixels (third color resist region), the color filter layer can have pixels corresponding to the colors include W (white), Y (Yellow) and etc., the performance of the display is also better; the black matrix, BM 3 is used to prevent leakage of the background light, improve display contrast, to prevent color mixing and increase the purity of color. The active switches can employ a thin film transistor.

According to another embodiment of the present application, the display panel includes a substrate, the substrate includes a first substrate 11 carrying the photo spacers 4 and a second substrate 12 for pressing the photo spacers 4, the manufacturing method including the steps of:

Disposing photo spacers 4 between the first substrate and the second substrate,

Bonding the second substrate 12 to the photo spacers 4 and applies pressure to the photo spacers 4; the photo spacers 4 include a pressing material layer, the pressing material layer has a function of being cured and shaped when subjected to a pressure.

According to another embodiment of the present application, the display panel includes a substrate, a frame 5 and a liquid crystals, the substrate including a first substrate 11 carrying the photo spacers 4 and a second substrate 12 for pressing the photo spacers 4, the manufacturing method including the steps of:

Disposing photo spacers 4 between the first substrate and the second substrate,

Setting the frame 5 surrounding the first substrate 11;

Drip-feeding the liquid crystals on the first substrate 11,

The second substrate 12 is bonded to the photo spacers 4 and applies pressure to the photo spacers 4; the photo spacers 4 include a pressing material layer, the pressing material layer has a function of being cured and shaped when subjected to a pressure. According to the steps of one drop filling, after coating the frame 5, the liquid crystals are filled and bonded to another substrate. The frame 5 can be thermally cured material, UV curing material.

According to another embodiment of the present application, the display panel includes a substrate, the substrate includes a first substrate 11 carrying the photo spacers 4 and a second substrate 12 for pressing the photo spacers 4, the manufacturing method including the steps of:

Disposing an alignment film on the inner surface of the first substrate and the second substrate,

Coating the resist of the photo spacers 41 on the first substrate 11, and the resist of the photo spacers 41 is exposed and developed,

Bonding the second substrate 12 to the photo spacers 4 and applies pressure to the photo spacers 4; the photo spacers 4 include a pressing material layer, the pressing material layer has a function of being cured and shaped when subjected to a pressure. The polyimide (P1) can be processed to provide a function of alignment of the liquid crystals; the coating can be performed by using a yellow resist of the photo spacers 41.

According to another embodiment of the present application, as illustrate in FIG. 4, the display panel includes a substrate, the substrate includes a first substrate 11 carrying the photo spacers 4 and a second substrate 12 for pressing the photo spacers 4, the manufacturing method including the steps of:

Disposing an alignment film on the inner surface of the first substrate and the second substrate,

Coating the resist of the photo spacers 41 on the first substrate 11, and the resist of the photo spacers 41 is exposed and developed,

Setting the frame 5 surrounding the first substrate 11;

Drip-feeding the liquid crystals, on the first substrate 11,

Bonding the second substrate 12 to the photo spacers 4 and applies pressure to the photo spacers 4; the photo spacers 4 include a pressing material layer, the pressing material layer has a function of being cured and shaped when subjected to a pressure. The polyimide can be processed to provide a function of alignment of the liquid crystals. The coating can be performed by using a yellow resist of the photo spacers 41. According to the steps of one drop filling, after coating the frame 5, the liquid crystals are filled and bonded to another substrate. The frame 5 can be thermally cured material, UV curing material.

Wherein as shown in FIG. 2, an alignment film is disposed on the inner surface of the first substrate 11 and the second substrate 12 as shown in the upper left side of the figure when the first substrate 11 and the second substrate 12 are opposite disposed. The resist of the photo spacers 41 is coated and disposed on the first substrate 11 as shown in the middle upper of the figure; the resist of the photo spacers 41 is exposed as shown in the upper right side of the figure; the lower right side of the figure shows the development process of the resist of the photo spacers 41; the lower left side of the figure shows bonding the second substrate 12 to the photo spacers 4 and applies pressure to the photo spacers 4.

According to another embodiment of the present application, the display apparatus disclosed in the present embodiment includes a backlight module and a display panel. The display panel includes a substrate; photo spacers 4, the photo spacers 4 are also disposed between the first substrate and the second substrate, the photo spacers 4 include a pressing material layer, the pressing material layer has a function of being cured and shaped when subjected to a pressure. The photo spacers 4 include a layer of pressing material layer, the pressing material layer has a function of being cured and shaped when subjected to the pressure, the photo spacers 4 is easily compressed, cured and shaped to reduce variations during the method for manufacturing the photo spacers.

It should be noted that, in the above-described embodiment, the material of the substrate can be glass, plastic or the like, and is not limited thereto.

In the above-described embodiment, the photo spacers 4 can be entirely made of a pressing material. The material of the pressing material can be selected from a transparent pressure-sensitive adhesive material, for example, styrene-butadiene rubber, polyisobutylene and butyl rubber, and etc. used as a main component. Styrene-butadiene rubber, SBR, also known as polystyrene butadiene copolymer. Its physical structure properties, processing performance and the use of products are close to the performance of natural rubber, some properties such as wearable, heat resistant, resistant to aging and rate of vulcanization is faster than natural rubber.

It can be used with natural rubber and a variety of synthetic rubber and the combination thereof. Butyl rubber is a kind of synthetic rubber, it is synthesized from isobutylene and a small amount of isoprene. Good air tightness. It can also with the properties such as heat resistant, resistant to ozone, resistant to aging, resistant chemicals, and shock absorption, electrical insulation. It has good resistance to sunlight and ozone, and can be exposed to animal or vegetable oils or oxidizable chemicals.

In the above embodiment, the display panel can include a liquid crystals panel, a curved panel, and the like. Taken the liquid crystals panel as an example, the liquid crystals panel includes a thin film Transistor Substrate (TFT Substrate) and a color filter substrate (CF Substrate), the array substrate is disposed opposite to the color filter substrate, and a liquid crystals (LC) and photo spacers (PS) are disposed between the array substrate and the color filter substrate, the array substrate is provided with a thin film transistor (TFT), the color filter substrate is provided with a color filter layer.

In the above embodiment, the color filter substrate can include a TFT array, that is the color filter layer and the TFT array can be formed on the same substrate, and the array substrate can include a color filter layer.

In the above-described embodiment, the display panel of the present application can be a curved type panel.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A display panel, comprising:
a first substrate;
a second substrate;
photo spacers disposed between the first substrate and the second substrate, wherein the first substrate is used for carrying the photo spacers; the second substrate is used for pressing the photo spacers; the photo spacers comprise a pressing material layer, the pressing material layer is cured and shaped when subjected to a pressure; and
wherein the photo spacers are disposed on the first substrate, the second substrate is bonded to the photo spacers and applies pressure to the photo spacers; the first substrate comprises active switches, the photo spacers are disposed on the active switches, the photo spacers comprise first end faces and second end faces, the first end faces are in contact with and connected to the first substrate, the second end faces are in contact with and connected to the second substrate, contact areas of the first end faces and the first substrate are larger than contact areas of the second end faces and the second substrate; or the first substrate comprises a color filter layer, the photo spacers are disposed on the color filter layer, the photo spacers comprise the first end faces and the second end faces, the first end faces are in contact with and connected to the first substrate, the second end faces are in contact with and connected to the second substrate, and the contact areas of the first end faces and the first substrate are larger than the contact areas of the second end faces and the second substrate; or the first substrate comprises the active switches and the color filter layer, the photo spacers are disposed on the active switches and the color filter layer, the photo spacers comprise the first end faces and the second end faces, the first end faces are in contact with and connected to the first substrate, the second end faces are in contact with and connected to the second substrate, and the contact areas of the first end faces and the first substrate are larger than the contact areas of the second end faces and the second substrate.

2. A display panel, comprising:
a first substrate;
a second substrate; and
photo spacers disposed between the first substrate and the second substrate, wherein the first substrate is used for carrying the photo spacers; the second substrate is used for pressing the photo spacers; the photo spacers comprise a pressing material layer, the pressing material layer is cured and shaped when subjected to a pressure.

3. The display panel according to claim 2, wherein the photo spacers are disposed on the first substrate, the second substrate is bonded to the photo spacers and applies pressure to the photo spacers.

4. The display panel according to claim 2, wherein the first substrate comprises active switches, the photo spacers are disposed on the active switches, the photo spacers comprise first end faces and second end faces, the first end faces are in contact with and connected to the first substrate, the second end faces are in contact with and connected to the second substrate, contact areas of the first end faces and the first substrate are larger than contact areas of the second end faces and the second substrate.

5. The display panel according to claim 2, wherein the photo spacers are disposed on the first substrate, the second substrate is bonded to the photo spacers and applies pressure to the photo spacers; the first substrate comprises active switches, the photo spacers are disposed on the active switches, the photo spacers comprise first end faces and second end faces, the first end faces are in contact with and connected to the first substrate, the second end faces are in contact with and connected to the second substrate, contact areas of the first end faces and the first substrate are larger than contact areas of the second end faces and the second substrate.

6. The display panel according to claim 2, wherein the first substrate comprises a color filter layer, the photo spacers are disposed on the color filter layer, the photo spacers comprise first end faces and second end faces, the first end faces are in contact with and connected to the first substrate, the second end faces are in contact with and connected to the second substrate, and contact areas of the first end faces and the first substrate are larger than contact areas of the second end faces and the second substrate.

7. The display panel according to claim 2, wherein the photo spacers are disposed on the first substrate, the second substrate is bonded to the photo spacers and applies pressure to the photo spacers; the first substrate comprises a color filter layer, the photo spacers are disposed on the color filter layer, the photo spacers comprise first end faces and second end faces, the first end faces are in contact with and connected to the first substrate, the second end faces are in contact with and connected to the second substrate, and contact areas of the first end faces and the first substrate are larger than contact areas of the second end faces and the second substrate.

8. The display panel according to claim 2, wherein the first substrate comprises active switches and an color filter layer, the photo spacers are disposed on the active switches and the color filter layer, the photo spacers comprise first end faces and second end faces, the first end faces are in contact with and connected to the first substrate, the second end faces are in contact with and connected to the second substrate, and contact areas of the first end faces and the first substrate are larger than contact areas of the second end faces and the second substrate.

9. The display panel according to claim 2, wherein the photo spacers are disposed on the first substrate, the second substrate is bonded to the photo spacers and applies pressure to the photo spacers; the first substrate comprises active switches and an color filter layer, the photo spacers are disposed on the active switches and the color filter layer, the photo spacers comprise first end faces and second end faces, the first end faces are in contact with and connected to the first substrate, the second end faces are in contact with and connected to the second substrate, and contact areas of the first end faces and the first substrate are larger than contact areas of the second end faces and the second substrate.

10. The display panel according to claim 2, wherein the photo spacers are disposed on the first substrate, the second substrate is bonded to the photo spacers and applies pressure to the photo spacers; the first substrate comprises active switches, the photo spacers are disposed on the active switches, the photo spacers comprise first end faces and second end faces, the first end faces are in contact with and connected to the first substrate, the second end faces are in contact with and connected to the second substrate, contact areas of the first end faces and the first substrate are larger than contact areas of the second end faces and the second substrate; or the first substrate comprises a color filter layer, the photo spacers are disposed on the color filter layer, the photo spacers comprise the first end faces and the second end faces, the first end faces are in contact with and connected to the first substrate, the second end faces are in contact with and connected to the second substrate, and the contact areas of the first end faces and the first substrate are larger than the contact areas of the second end faces and the second substrate; or the first substrate comprises the active switches and the color filter layer, the photo spacers are disposed on the active switches and the color filter layer, the photo spacers comprise the first end faces and the second end faces, the first end faces are in contact with and connected to the first substrate, the second end faces are in contact with and connected to the second substrate, and the contact areas of the first end faces and the first substrate are larger than the contact areas of the second end faces and the second substrate.

11. The display panel according to claim 8, wherein the color filter layer comprises color resist regions; the active switches comprise a protective layer and a transparent conductive layer, the protective layer and the transparent conductive layer are disposed on the corresponding color resist regions; the side portion of the color resist region comprises a capping layer; the capping layer is formed by the protective layer and the transparent conductive layer between two adjacent color resist regions of the two sides of the corresponding color resist regions; and the active switches are disposed on the first substrate.

12. The display panel according to claim 2, wherein the first substrate comprises active switches and an color filter layer, the photo spacers are disposed on the active switches and the color filter layer, the photo spacers comprise first end faces and second end faces, the first end faces are in contact with and connected to the first substrate, the second end faces are in contact with and connected to the second substrate, and contact areas of the first end faces and the first substrate are larger than contact areas of the second end faces and the second substrate; the color filter layer comprises color resist regions; the active switches comprise a protective layer and a transparent conductive layer, the protective layer and the transparent conductive layer are disposed on the corresponding color resist regions; the side portion of the color resist region comprises a capping layer; the capping layer is formed by the protective layer and the transparent conductive layer between two adjacent color resist regions of the two sides of the corresponding color resist regions; and the active switches are disposed on the first substrate.

13. The display panel according to claim 2, wherein the photo spacers are disposed on the first substrate, the second substrate is bonded to the photo spacers and applies pressure to the photo spacers; the first substrate comprises active switches and an color filter layer, the photo spacers are disposed on the active switches and the color filter layer, the photo spacers comprise first end faces and second end faces, the first end faces are in contact with and connected to the first substrate, the second end faces are in contact with and connected to the second substrate, and contact areas of the first end faces and the first substrate are larger than contact areas of the second end faces and the second substrate; the color filter layer comprises color resist regions; the active switches comprise a protective layer and a transparent conductive layer, the protective layer and the transparent conductive layer are disposed on the corresponding color resist regions; the side portion of the color resist region comprises a capping layer; the capping layer is formed by the protective layer and the transparent conductive layer between two adjacent color resist regions of the two sides of the corresponding color resist regions; and the active switches are disposed on the first substrate.

14. A method for manufacturing a display panel, the display panel comprising a first substrate used for carrying photo spacers and a second substrate used for pressing the photo spacers, the method comprising the steps of:
disposing photo spacers between the first substrate and the second substrate;
bonding the second substrate to the photo spacers and applying pressure to the photo spacers; and
wherein the photo spacers comprise a pressing material layer, the pressing material layer is cured and shaped when subjected to a pressure.

15. The method for manufacturing the display panel according to claim 14, wherein the display panel further comprises a frame and liquid crystals, the steps between disposing photo spacers between the first substrate and the second substrate and bonding the second substrate to the photo spacers and applying pressure to the photo spacers further comprises the step of:
setting the frame surrounding the first substrate; and
drip-feeding the liquid crystals on the first substrate.

16. The method for manufacturing the display panel according to claim 14, wherein the display panel further comprises a frame and liquid crystals and the method further comprises the steps of:
disposing photo spacers between the first substrate and the second substrate;
setting the frame surrounding the first substrate;
drip-feeding the liquid crystals on the first substrate;
bonding the second substrate to the photo spacers and applies pressure to the photo spacers; and
wherein the photo spacers comprise a pressing material layer, the pressing material layer is cured and shaped when subjected to a pressure.

17. The method for manufacturing the display panel according to claim 14, further comprising a step before the step of disposing photo spacers between the first substrate and the second substrate of:
disposing alignment films on opposite inner surfaces of the first substrate and the second substrate, and
coating resists of the photo spacers on the first substrate, and exposing and developing the resist of the photo spacers.

18. The method for manufacturing the display panel according to claim 14, wherein the method comprises the steps of:
disposing alignment films on opposite inner surfaces of the first substrate and the second substrate;
coating resists of the photo spacers on the first substrate, and exposing and developing the resist of the photo spacers;
disposing photo spacers between the first substrate and the second substrate;
bonding the second substrate to the photo spacers and applying pressure to the photo spacers; and
wherein the photo spacers comprise a pressing material layer, the pressing material layer is cured and shaped when subjected to a pressure.

19. The method for manufacturing the display panel according to claim 14, wherein the display panel further comprises a frame and liquid crystals and the method comprises the steps of:
disposing alignment films on opposite inner surfaces of the first substrate and the second substrate;
coating resists of the photo spacers on the first substrate, and exposing and developing the resist of the photo spacers;
disposing photo spacers between the first substrate and the second substrate;
setting the frame surrounding the first substrate;
drip-feeding the liquid crystals on the first substrate;
bonding the second substrate to the photo spacers and applying pressure to the photo spacers; and
wherein the photo spacers comprise a pressing material layer, the pressing material layer is cured and shaped when subjected to a pressure.
